(19) United States
(12) Patent Application Publication
(10) Pub. No.: US 2025/0331098 A1
(43) Pub. Date: Oct. 23, 2025

(54) CIRCUIT BOARD

(71) Applicant: LG INNOTEK CO., LTD., Seoul (KR)

(72) Inventors: Woo Seop SIM, Seoul (KR); Moo Seong KIM, Seoul (KR)

(73) Assignee: LG INNOTEK CO., LTD., Seoul (KR)

(21) Appl. No.: 18/707,433

(22) PCT Filed: Nov. 4, 2022
(86) PCT No.: PCT/KR2022/017257

§ 371 Date: Dec. 6, 2024

(30) Foreign Application Priority Data
Nov. 5, 2021 (KR) 10-2021-0151768

(51) Int. Cl. H05K 1/02; H05K 1/11; H05K 1/18; H05K 3/46

(52) U.S. Cl. CPC H05K 1/0242; H05K 1/113; H05K 1/181; H05K 3/4644; H05K 2201/09481; H05K 2201/096; H05K 2201/09827; H05K 2201/10212

(57) ABSTRACT

A circuit board according to an embodiment includes a first pad; an insulating layer disposed on the first pad; a second pad disposed on the insulating layer; and a through electrode formed in a through hole passing through the insulating layer and connecting the first pad and the second pad, wherein the through electrode includes a first metal layer formed on an inner wall of the through hole; and a second metal layer formed on the first metal layer and filling the through hole, the first pad is in contact with a lower surface of the through electrode and has a thickness in a range of 1.0 μm to 12 μm, and the second pad includes a third metal layer extending from the first metal layer; and a fourth metal layer extending from the second metal layer.

### TECHNICAL FIELD

The embodiment relates to a circuit board and a semiconductor package including the same.

### BACKGROUND ART

A printed circuit board (PCB) is formed by printing a circuit line pattern with a conductive material such as copper on an electrically insulating board, and refers to a board immediately before mounting electronic components. In other words, it refers to a circuit board in which a mounting position of each component is determined and a circuit pattern connecting the components is printed and fixed on the surface of the flat plate in order to densely mount many different types of electronic devices on a flat plate.

Signals generated from the components mounted on the printed circuit board can be transmitted through circuit patterns connected to each component.

Meanwhile, in order to perform high-speed processing of large amounts of information with the recent advancement in functionality of portable electronic devices, etc., signals are becoming higher frequency, and circuit patterns for printed circuit boards suitable for high-frequency applications are required.

In this case, the circuit pattern of the printed circuit board must minimize signal transmission loss to enable signal transmission without deteriorating the quality of high-frequency signals.

The insulating layer used in circuit boards for high-frequency applications must have isotropy of electrical properties for ease of circuit pattern design and processing, low reactivity with metal wiring materials, low ionic transferability and sufficient mechanical strength to withstand processes such as chemical mechanical polishing (CMP), peeling or low moisture absorption rate to prevent dielectric constant increase, heat resistance to withstand process processing temperatures, and a low thermal expansion coefficient to eliminate cracks due to temperature changes.

In addition, the insulating layer used in circuit boards for high-frequency applications must satisfy various conditions, such as adhesion that can minimize various stresses and peeling occurring at the interface with the metal thin film layer, crack resistance, low stress and low high-temperature gas generation, etc., and for this purpose, resin coated copper (RCC) is used.

However, in these resin coated copper, a filler content is reduced in order to achieve a low dielectric constant, and as the filler content decreases, it is difficult to realize a normal through hole shape. For example, when forming a through hole in low dielectric constant copper foil adhesive resin using a laser drill method, there are limitations in forming the through hole of a desired fine size (for example, 50 μm or less).

Accordingly, for circuit integration, a new circuit board including a fine through hole and a fine through electrode is required.

### DISCLOSURE

### Technical Problem

An embodiment provides a circuit board including a fine through electrode and a semiconductor package including the same.

In addition, the embodiment provides a circuit board capable of minimizing a deviation in width for each region in a thickness direction of a through electrode and a semiconductor package including the same.

In addition, the embodiment provides a circuit board capable of minimizing a thickness of a circuit pattern layer and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment includes a first pad; an insulating layer disposed on the first pad; a second pad disposed on the insulating layer; and a through electrode formed in a through hole passing through the insulating layer and connecting the first pad and the second pad, wherein the through electrode includes: a first metal layer formed on an inner wall of the through hole; and a second metal layer formed on the first metal layer and filling the through hole, the first pad is in contact with a lower surface of the through electrode and has a thickness in a range of 1.0 μm to 12 μm, and the second pad includes: a third metal layer extending from the first metal layer; and a fourth metal layer extending from the second metal layer.

In addition, the first metal layer and the third metal layer are one metal layer formed integrally, and the second metal layer and the fourth metal layer are one metal layer formed integrally.

In addition, the second pad is in contact with an upper surface of the through electrode and has a thickness in a range of 1.0 μm to 12 μm.

In addition, the through electrode has a first width at an upper surface and a second width less than the first width at a first region below the upper surface, and the first region is a region with a smallest width in an entire region in a thickness direction of the through electrode, and the second width satisfies a range of 70% to 99% of the first width.

In addition, the first width is one of a maximum width and an average width of the upper surface of the through electrode.

In addition, one half of a difference value between the first width and the second width of the through electrode satisfies a range of 0.1% to 20% of the first width.

In addition, the second pad has a third width, and one half of a difference value between the third width of the second pad and the second width of the through electrode is 4.0 μm or less.

In addition, the second pad has a third width, and one half of a difference value between the third width of the second pad and the first width of the through electrode satisfies a range of 0.75 μm to 2.97 μm.

In addition, the third metal layer of the second pad is disposed on an upper surface of the insulating layer, the fourth metal layer of the second pad is disposed on the third metal layer, and a thickness of the second pad is a sum of thicknesses of the third metal layer and the fourth metal layer.

In addition, the second pad includes a copper foil layer disposed between the insulating layer and the third metal layer, and the thickness of the second pad is a sum of a thickness of the copper foil layer, a thickness of the third metal layer, and a thickness of the fourth metal layer.

In addition, the third metal layer of the second pad does not directly contact the upper surface of the insulating layer.

In addition, a side surface of the copper foil layer of the second pad has a first inclination angle, and a side surface of the through electrode has a second inclination angle different from the first inclination angle.

In addition, the insulating layer includes either RCC (Resin coated copper) or prepreg.

In addition, the insulating layer has a dielectric constant (Dk) between 2.0 and 3.0.

Meanwhile, a semiconductor package according to the embodiment includes a plurality of insulating layers; a plurality of circuit pattern layers disposed on the plurality of insulating layers; a through electrode passing through the plurality of insulating layers and connecting circuit pattern layers disposed on different insulating layers; a connection part disposed on an outermost circuit pattern layer among the plurality of circuit pattern layers; a chip disposed on the connection part; and a molding layer for molding the chip, wherein the plurality of circuit pattern layers includes: a pad in contact with the through electrode and having a thickness in a range of 1.0 μm to 12 μm, the through electrode has a first width at an upper surface and a second width less than the first width at a first region below the upper surface, the first region is a region with a smallest width in an entire region in a thickness direction of the through electrode, and the second width satisfies a range of 70% to 99% of the first width.

In addition, the chip includes a first chip and a second chip arranged to be spaced apart from each other in a width direction, the first chip corresponds to a central processor (CPU), and the second chip corresponds to a graphics processor (GPU).

### Advantageous Effects

The embodiment manufactures a circuit board using RCC or prepreg rather than a photosensitive material. That is, PID, which is generally a photosensitive material, has a dielectric constant (Dk) exceeding 3.0, and accordingly, it is difficult to apply it to boards that use frequencies higher than those for 5G. For example, in a 5G board, a dielectric constant of the board must be low. However, the dielectric constant of general PID exceeds 3.0. Accordingly, when applying the PID to a 5G board, there is a problem that signal transmission loss increases when transmitting a large signal. In addition, when a circuit board is implemented using a PID, a sputter, which is a deposition equipment, must be used in the plating process for circuit formation on the circuit board including the PID, which has the problem of increasing process costs. Furthermore, in the circuit board including the PID, there is a problem in that the adhesion between the insulating layer composed of the PID and the circuit pattern is low, and as a result, the circuit pattern is separated from the insulating layer. For example, the circuit board including a PID requires a high process temperature (e.g., 250 degrees or more) during the circuit pattern formation process or soldering process. Due to such a high process temperature, the adhesion between the PID and the circuit pattern is reduced, causing the circuit pattern to be separated from the insulating layer.

Accordingly, the insulating layer in the embodiment may be formed of RCC or prepreg having a dielectric constant (Dk) between 2.0 and 3.0. Accordingly, the embodiment provides a circuit board with a low dielectric constant, enabling application to 5G products and solving the reliability problem of the PID.

Meanwhile, an insulating layer containing RCC or prepreg has a limitation in forming a small or fine through electrode. At this time, when forming a through hole in the insulating layer with a copper foil layer laminated on a surface, the embodiment allows for the copper foil layer to be preferentially removed. For example, the embodiment allows to preferentially remove by etching some regions of the copper foil layer corresponding to a location where the through hole is to be formed. In addition, the embodiment proceeds with a laser processing process on the surface of the insulating layer exposed as the copper foil layer is removed. That, the embodiment proceeds with a process of forming a through hole of a desired size. Accordingly, the embodiment allows only the insulating layer to be processed in a process of forming the through hole. Accordingly, an intensity of the laser can be lowered compared to a comparative example. Through this, the embodiment can reduce a difference value between a maximum width and a minimum width of the through hole, thereby enabling the formation of a small or fine through electrode.

In addition, the embodiment can reduce the laser intensity in the through hole formation process as described above, and thus reduce a thickness of the pad of the circuit pattern layer that functions as a stopper in a laser process. Accordingly, the embodiment can reduce a thickness of the circuit pattern layer and further reduce a thickness of the insulating layer covering the circuit pattern layer, thereby enabling slimming of the circuit board.

Meanwhile, in circuit boards for 5G or higher, signals in the high frequency band are transmitted through the circuit pattern layer. At this time, the signal in the high frequency band has the characteristic of moving along a surface of the circuit pattern layer. And, when a roughness of the circuit pattern layer increases or a surface area of the circuit pattern layer increases, signal transmission loss increases due to a skin effect. At this time, the embodiment may reduce the thickness of the circuit pattern layer as described above compared to the comparative example. Through this, the embodiment can reduce a surface area of the first circuit pattern layer 120 and the second circuit pattern layer 130, and thereby minimize signal transmission loss.

### DESCRIPTION OF DRAWINGS

FIG. 1A is a view showing a through hole forming process according to a comparative example.

FIG. 1B is a view showing a processing problem in a process of forming a through hole in a comparative example.

FIG. 1C is a view showing a size of a through hole according to a comparative example.

FIG. 1D is a view showing a circuit board according to a comparative example.

FIG. 2 is a view showing a circuit board according to a first embodiment.

FIG. 3 is a first enlarged view of region A of FIG. 2.

FIG. 4 is a second enlarged view of region A of FIG. 2.

FIG. 5 is an enlarged view of a through electrode of FIG. 2.

FIG. 6 is a view showing an actual product photo of a through hole formed according to a first embodiment.

FIG. 7 is a view showing a circuit board according to a second embodiment.

FIG. 8 is a view showing a semiconductor package according to an embodiment.

FIGS. 9 to 16 are views showing the manufacturing method of the circuit board shown in FIG. 2 in order of processes.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Before explaining a present embodiment, a circuit board of a comparative example compared to this embodiment will be described.

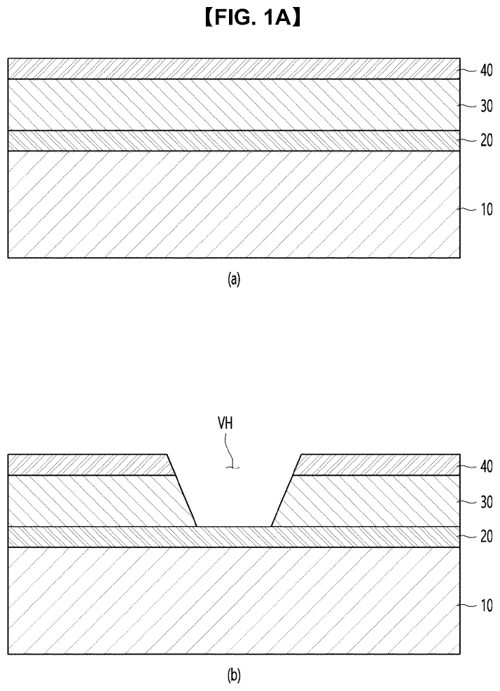

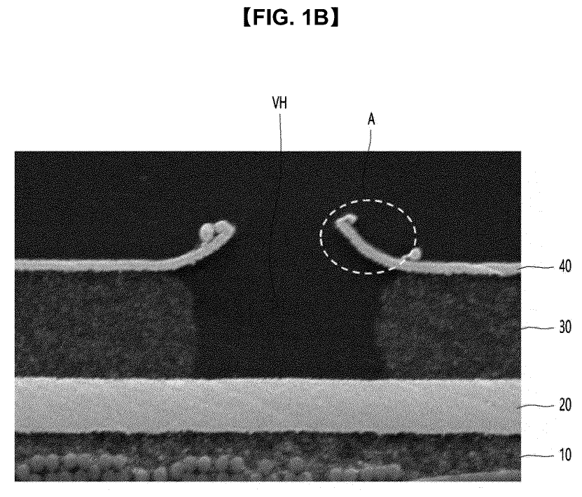

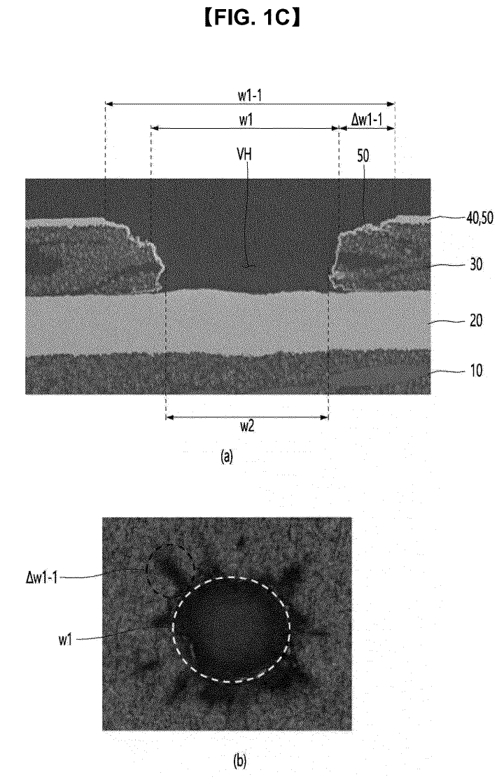

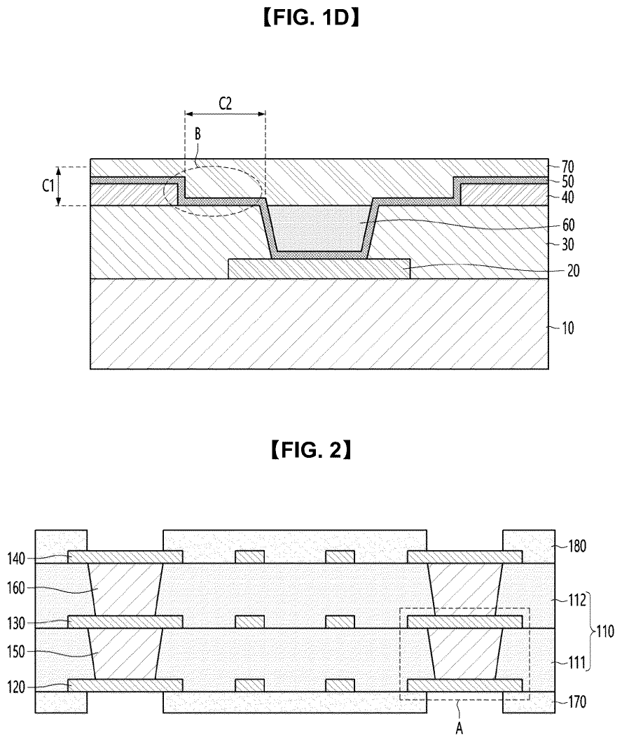

FIG. 1A is a view showing a through hole forming process according to a comparative example, FIG. 1B is a view showing a processing problem in a process of forming a through hole in a comparative example, FIG. 1C is a view showing a size of a through hole according to a comparative example, and FIG. 1D is a view showing a circuit board according to a comparative example.

Referring to FIGS. 1A to 1D, in the comparative example, it is difficult to refine a size of a through hole, and further, there is a limit to miniaturizing a size of a through electrode filling an inside of the through hole.

As shown in (a) of FIG. 1A, the circuit board in the comparative example has a laminated structure including a substrate 10, a metal layer 20, an insulating layer 30, and a copper foil layer 40.

The substrate 10 may refer to one insulating layer among a plurality of insulating layers constituting a circuit board, or, alternatively, may be a support substrate formed to manufacture a coreless substrate.

When the substrate 10 refers to one insulating layer among a plurality of insulating layers, the metal layer 20 may refer to a through electrode pad connected to a through electrode among circuit patterns disposed on the one insulating layer. In addition, when the substrate 10 refers to a support substrate, the metal layer 20 may refer to a copper foil layer disposed on the support substrate.

Generally, a circuit board is made by stacking an insulating layer 30 and a copper foil layer 40 on the substrate 10 and the metal layer 20 and forming a circuit pattern layer or through electrode using the insulating layer 30 and the copper foil layer 40.

The insulating layer 30 is made of prepreg or RCC (resin coated copper).

At this time, in the comparative example, as shown in (b) of FIG. 1a, a through hole VH is formed that exposes the upper surface of the metal layer 20 while penetrating the insulating layer 30 and the copper foil layer 40 by irradiating a laser (not shown) on the insulating layer 30 and the copper foil layer 40. At this time, the laser may be a carbon dioxide (CO₂) laser, and the insulating layer 30 and the copper foil layer 40 are simultaneously processed using this laser to form the through hole VH.

At this time, a laser processing degree of the insulating layer 30 and a laser processing degree 40 of the copper foil layer 40 appear different from each other. For example, a strength of the insulating layer 30 and a strength of the copper foil layer 40 are different from each other. Accordingly, when a laser of a certain intensity is irradiated, a degree of processing of the insulating layer 30 and a degree of processing of the copper foil layer 40 appear to be different from each other.

Accordingly, when the laser irradiation intensity is lowered than a reference value, as shown in FIG. 1B, there is debris (A) such as a burr that is not completely removed from the copper foil layer 40 in a region that overlaps the through hole VH in a vertical direction. The debris (A) connects circuit pattern layers or through electrodes that should be electrically separated from each other, which causes problems such as electrical shorts.

Therefore, in the comparative example, the laser irradiation intensity is increased to completely remove debris (A) such as burrs from the copper foil layer 40.

At this time, when forming a through hole VH as in the comparative example, there is a problem in that the size of the through hole VH becomes larger than a target size. For example, when forming a through hole VH as in the comparative example, there is a limit to reducing a size of the through hole.

In addition, in the comparative example, there is a problem in which the laser is intensively irradiated to an upper region of the insulating layer 30 adjacent to the copper foil layer 40, and as a result, there is a problem in that an upper width of the through hole VH becomes larger than the target size. Through this, the comparative example has a problem in that the difference value between the maximum and minimum widths of the through hole VH increases.

Specifically, as shown in (a) and (b) of FIG. 1C, in the comparative example, a target size is determined such that a maximum width of the through hole VH is allowed to have a first width (w1) and a minimum width of the through hole VH is allowed to have a second width (w2). And, the through hole formation process is performed based on the target size determined above.

However, in the comparative example, the insulating layer 30 and the copper foil layer 40 are processed together to form a through hole VH, so that there is a problem in that the maximum width of the through hole VH has a first-first width (w1-1) that is larger than the first width (w1). That is, in the comparative example, an upper region of the through hole VH is provided with a step region having a first-first width (w1-1) that is larger than the first width (w1) by a first difference value (Δw1-1).

Therefore, the through hole VH in the comparative example has a maximum width of the first-first width (w1-1) and a minimum width of the second width (w2). Accordingly, the second width (w2) of the through hole VH in the comparative example has a value of 60% or less of the first-first width (w1-1). In addition, the circuit board in the comparative example has a problem in that the difference value between the maximum and minimum widths of the through electrode that fill the through hole VH is large, and as a result, there is a problem of increased signal transmission loss.

In addition, the through hole VH in the comparative example includes a step region due to the difference value between the maximum and minimum widths as described above. In addition, in the comparative example, it is difficult to determine the exact size of the through hole VH due to the step region of the through hole VH, and furthermore, there is a problem in that it is difficult to accurately determine the size of the through electrode that fills the inside of the through hole.

For example, in the comparative example, a step region is formed in a region corresponding to the first difference value (Δw1-1) in FIG. 1C. And, generally, both the copper foil layer 40 and the first metal layer 50 must be present on the upper surface of the insulating layer 20. However, in the comparative example, the copper foil layer 40 in the step region is removed, so that only the first metal layer 50 exists.

Specifically, as shown in FIG. 1D, in the comparative example, when the through hole VH is formed in order to form a through electrode, a seed layer such as the first metal layer 50 is formed on the inner wall of the through hole VH and the copper foil layer 40. Thereafter, in the comparative example, the first metal layer 50 is electroplated with a seed layer to fill the inside of the through hole VH, forming second metal layers 60 and 70 extending to an upper portion thereof.

However, the comparative example has a step region as the laser irradiation conditions for removing the copper foil layer 40 are applied during the formation of the through hole VH, and accordingly, there is a problem in that a step portion B is provided between the copper foil layer 40 and the first metal layer 50 on the upper surface of the insulating layer 30.

For example, in a process of forming the through hole VH, the copper foil layer 40 is removed while having a width greater than the upper width of the through hole VH, and accordingly, the first metal layer 50 is disposed on the inner wall of the copper foil layer 40 and the upper surface of the insulating layer 30. At this time, the step portion (B) acts as a factor causing signal loss in a situation that signals are transmitted through the circuit pattern or through electrode.

At this time, in the comparative example, the laser process conditions in the process of forming the through hole VH are set to conditions for removing the copper foil layer 40, and accordingly, a length of the step portion B in a horizontal direction increases. Additionally, as the length of the step portion B increases in the horizontal direction, there is a problem that the size of the through hole and the size of the through electrode increases.

Specifically, in the comparative example, a horizontal length C2 of the step portion B is greater than a thickness C1 of the circuit pattern. For example, the thickness C1 of the circuit pattern in the comparative example corresponds to a sum of a thickness of the copper foil layer 40, a thickness of the first metal layer 50, and a thickness of the second plating layer 70. And, in the comparative example, the horizontal length C2 of the step portion B is greater than the thickness C1 of the circuit pattern (or a vertical length of the circuit pattern).

Accordingly, the embodiment provides a circuit board with a new structure that can eliminate the step portion while reducing the size of the through hole and the size of the through electrode, and a semiconductor package including the same.

In addition, the embodiment provides a circuit board with a new structure that can minimize the thickness of the circuit pattern layer of the circuit board and a semiconductor package including the same.

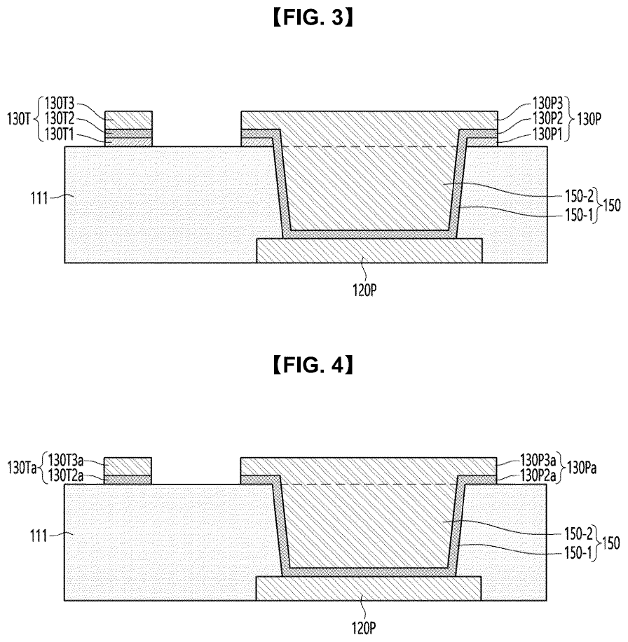

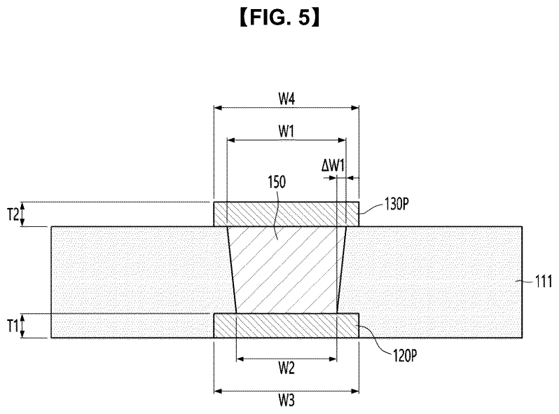

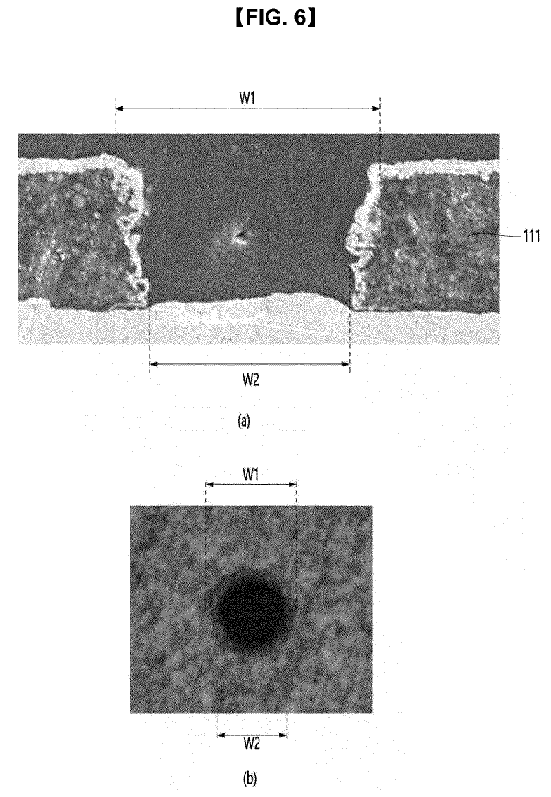

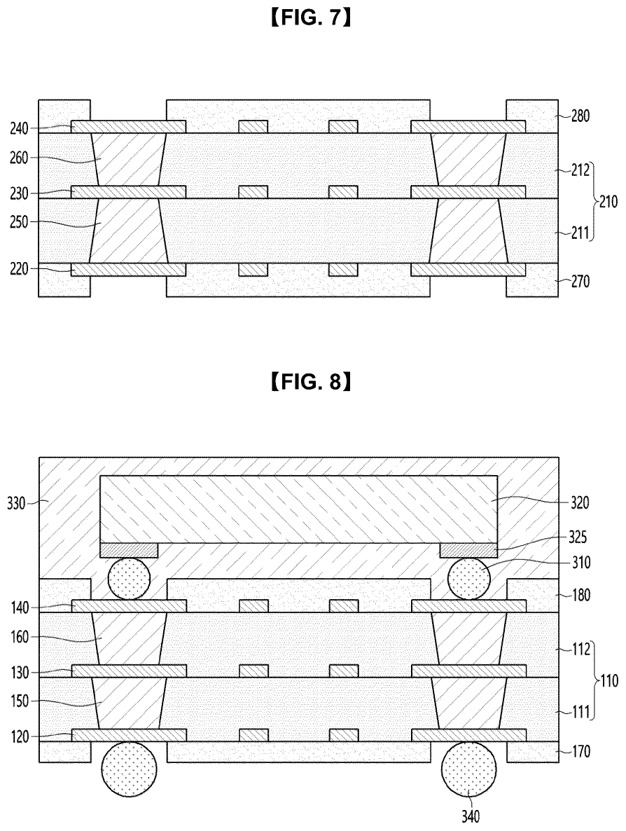

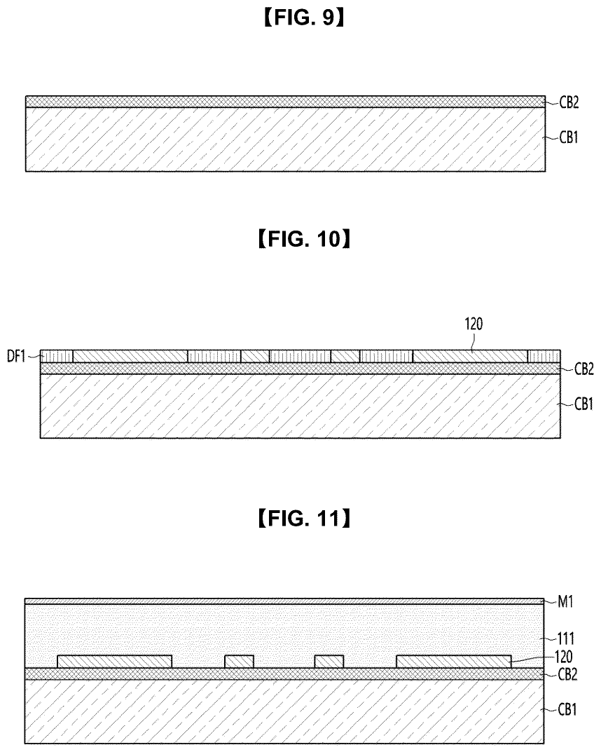

FIG. 2 is a view showing a circuit board according to a first embodiment, FIG. 3 is a first enlarged view of region A of FIG. 2, FIG. 4 is a second enlarged view of region A of FIG. 2, FIG. 5 is an enlarged view of a through electrode of FIG. 2, and FIG. 6 is a view showing an actual product photo of a through hole formed according to a first embodiment.

Hereinafter, the circuit board according to the first embodiment will be described in detail with reference to FIGS. 2 to 6.

In forming a through electrode by filling an inside of a through hole formed using a laser process with a conductive material, the circuit board of the embodiment allows to reduce a size of the through electrode, minimize a deviation in width for each region in the thickness direction of the through electrode, and minimize a thickness of the circuit pattern layer.

Hereinafter, the circuit board of the embodiment will be described in detail.

Referring to FIGS. 2 to 6, the circuit board includes an insulating layer 110, a circuit pattern layer, a through electrode, and a protective layer.

The insulating layer 110 may include a first insulating layer 111 and a second insulating layer 112. However, a layer structure of the insulating layer 110 of the embodiment is not limited thereto. For example, the insulating layer 110 may have a single-layer structure including only the first insulating layer 111. For example, the insulating layer 110 may have a three-layer or more layer structure in which at least one third insulating layer (not shown) is disposed between the first insulating layer 111 and the second insulating layer 112.

On the other hand, when the insulating layer 110 has a multiple layer structure, the first insulating layer 111 may refer to an insulating layer disposed at a lowest side among a plurality of layers, and the second insulating layer 112 may refer to an insulating layer disposed at an uppermost side among a plurality of layers.

The insulating layer 110 is a board on which an electric circuit whose wiring can be changed is organized, and may include both a print, a wiring board, and an insulating board made of insulating material capable of forming circuit patterns on its surface.

For example, at least one of the insulating layers 110 may be rigid or flexible. For example, at least one of the insulating layers 110 may include glass or plastic. Specifically, at least one of the insulating layers 110 may include a chemically tempered/semi-tempered glass, such as soda lime glass, aluminosilicate glass, etc., a tempered or flexible plastic such as polyimide (PI), polyethylene terephthalate (PET), propylene glycol (PPG), polycarbonate (PC), etc., or sapphire.

In addition, at least one of the insulating layers 110 may include an optically isotropic film. As an example, at least one of the insulating layers 110 may include cyclic olefin copolymer (COC), cyclic olefin polymer (COP), optically isotropic PC, optically isotropic polymethylmethacrylate (PMMA), or the like.

In addition, at least one of the insulating layers 110 may be formed of a material containing an inorganic filler and an insulating resin. For example, the material constituting the insulating layer 110 can be resins containing reinforcing materials such as inorganic fillers such as silica and alumina with thermosetting resins such as epoxy resins and thermoplastic resins such as polyimide, specifically ABF (Ajinomoto Build-up Film), FR-4, BT (Bismaleimide Triazine), PID (Photo Imageable Dielectric resin), BT, etc.

In addition, at least one of the insulating layers 110 may be partially bent while having a curved surface. That is, at least one of the insulating layers 110 may partially have a plane and may partially be bent while having a curved surface. Specifically, an end portion of at least one of the insulating layers 110 may be bent while having a curved surface, or bent or crooked while having a surface with a random curvature.

A circuit pattern layer may be disposed on a surface of the insulating layer 110.

For example, a first circuit pattern layer 120 may be disposed on the first or lower surface of the first insulating layer 111. For example, a second circuit pattern layer 130 may be disposed between the second surface or upper surface of the first insulating layer 111 and the first surface or lower surface of the second insulating layer 112. For example, a third circuit pattern layer 140 may be disposed on a second surface or upper surface of the second insulating layer 112.

For example, the first circuit pattern layer 120 may refer to a circuit pattern layer disposed on a lowermost side or first outermost side of the circuit board among a plurality of circuit pattern layers. For example, the third circuit pattern layer 140 may refer to a circuit pattern layer disposed on an uppermost side or second outermost side of the circuit board among a plurality of circuit pattern layers. In addition, the second circuit pattern layer 130 may mean a first inner circuit pattern layer adjacent to the first circuit pattern layer 120 among a plurality of circuit pattern layers, or a second inner circuit pattern layer adjacent to the third circuit pattern layer 140 among a plurality of circuit pattern layers.

The first circuit pattern layer 120, the second circuit pattern layer 130, and the third circuit pattern layer 140 are wirings that transmit electrical signals, and may be formed of a metal material having high electrical conductivity. To this end, the first circuit pattern layer 120, the second circuit pattern layer 130, and the third circuit pattern layer 140 may be formed of at least one metal material selected from gold (Au), silver (Ag), platinum (Pt), titanium (Ti), tin (Sn), copper (Cu), and zinc (Zn). In addition, the first circuit pattern layer 120, the second circuit pattern layer 130, and the third circuit pattern layer 140 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit pattern layer 120, the second circuit pattern layer 130, and the third circuit pattern layer 140 may be formed of copper (Cu), which has high electrical conductivity and is relatively inexpensive.

The first circuit pattern layer 120, the second circuit pattern layer 130, and the third circuit pattern layer 140 may be formed by an additive process, a subtractive process, a modified semi additive process (MSAP) and a semi additive process (SAP) method, which is a typical circuit board manufacturing process, and a detailed description thereof will be omitted herein. In addition, the first circuit pattern layer 120, the second circuit pattern layer 130, and the third circuit pattern layer 140 may have different layer structures depending on a manufacturing method. For example, each of the first circuit pattern layer 120, the second circuit pattern layer 130, and the third circuit pattern layer 140 may have a three-layer structure when manufactured using the MSAP method. As another example, the first circuit pattern layer 120, the second circuit pattern layer 130, and the third circuit pattern layer 140 may have a two-layer structure when manufactured using the SAP method. This will be explained below.

Meanwhile, each of the first to third circuit pattern layers 120, 130, and 140 includes a traces and a pad.

The trace refers to a long line-shaped wiring that transmits electrical signals. Additionally, the pad may refer to a mounting pad on which components such as chips are mounted, a core pad or BGA pad for connection to an external board, or a through electrode pad connected to a through electrode.

Meanwhile, the circuit board of the embodiment may have an Embedded Trace Substrate (ETS) structure. Accordingly, one of outermost circuit pattern layers of the circuit board may have a structure buried in an insulating layer. For example, the first circuit pattern layer 120 may have a structure embedded in the first insulating layer 111. For example, an upper surface of the first circuit pattern layer 120 may be positioned higher than a lower surface of the first insulating layer 111. In addition, at least a portion of a side surface of the first circuit pattern layer 120 may be covered with the first insulating layer 111.

A first protective layer 170 may be disposed on a first surface or lower of the first insulating layer 111. The first protective layer 170 may be solder resist, but is not limited thereto.

The first protective layer 170 may include a first opening (not shown) that vertically overlaps a lower surface of the first circuit pattern layer 120. For example, the first protective layer 170 may include a first opening (not shown) that vertically overlaps the pad 120P of the first circuit pattern layer 120.

Correspondingly, a second protective layer 180 may be disposed on a second or upper surface of the second insulating layer 112. The second protective layer 180 may be solder resist, but is not limited thereto. The second protective layer 180 may include a second opening (not shown) that vertically overlaps a pad (not shown) of the third circuit pattern layer 140.

Meanwhile, the circuit board of the embodiment includes a through electrode. The through electrode can electrically connect circuit pattern layers arranged in different layers.

For example, a first through electrode 150 is disposed in the first insulating layer 111. The first through electrode 150 passes through the first insulating layer 111. The first through electrode 150 may connect between the first circuit pattern layer 120 and the second circuit pattern layer 130.

For example, a second through electrode 160 is disposed in the second insulating layer 112. The second through electrode 160 may connect between the second circuit pattern layer 130 and the third circuit pattern layer 140.

The through electrodes 150 and 160 as described above can be formed by filling the inside of the through hole formed in each insulating layer with a metal material. The through hole may be formed by any one of machining methods, including mechanical, laser, and chemical processing. When the through hole is formed by mechanical processing, methods such as milling, drilling, and routing may be used, and when the through hole is formed by laser processing, a UV or CO₂ laser method may be used, and when the through hole is formed by chemical processing, chemicals containing amino silane, ketones, etc. may be used, and the like, thereby at least one insulating layer among the plurality of insulating layers may be opened.

When the through hole is formed, the through electrodes 150 and 160 may be formed by filling the inside of the through hole with a conductive material. Metal materials forming the through electrodes 150 and 160 may be any one material selected from Cu, Ag, Sn, Au, Ni, and Pd, and the metal material may be filled using any one or a combination of electroless plating, electrolytic plating, screen printing, sputtering, evaporation, ink jetting and dispensing.

Meanwhile, the circuit pattern layer and the through electrode in the embodiment may have a multiple layer structure. For example, the through electrodes 150 and 160 may have a two-layer structure. For example, the through electrodes 150 and 160 may have a three-layer structure. For example, when the circuit pattern layer and through electrode of the embodiment are manufactured by the MSAP method, the through electrodes 150 and 160 may have a three-layer structure. For example, when the circuit pattern layer and through electrode of the embodiment are manufactured using the SAP method, the through electrodes 150 and 160 may have a two-layer structure.

Meanwhile, at least one of the first circuit pattern layer 120, the second circuit pattern layer 130, and the third circuit pattern layer 140 may have the same layer structure as that of the through electrodes 150 and 160. For example, the second circuit pattern layer 130 and the third circuit pattern layer 140 may have the same layer structure as that of the through electrodes 150 and 160. The first circuit pattern layer 120 may have a layer structure different from that of the through electrodes 150 and 160.

That is, the circuit board of the first embodiment has an ETS structure. Accordingly, the first circuit pattern layer 120 may include only a one-layer metal layer (for example, a metal layer formed by electrolytic plating on a seed layer).

Hereinafter, a layer structure of the second circuit pattern layer 130 and the through electrodes 150 and 160 of the first embodiment will be described in more detail.

Hereinafter, a layer structure of the circuit pattern layer and a layer structure of the through electrode of the circuit board manufactured by the MSAP method will be described with reference to FIG. 3.

Referring to FIG. 3, the circuit board includes a first through electrode 150 passing through the first insulating layer 111. The circuit board includes a first circuit pattern layer 120 disposed on the lower surface of the first insulating layer 111 and a second circuit pattern layer 130 disposed on the upper surface of the first insulating layer 111.

The first circuit pattern layer 120 includes a first pad 120P that overlaps the first through electrode 150 in a vertical direction and is in direct contact with the lower surface of the first through electrode 150, and a trace (not shown) connected to the first pad 120P.

In addition, the second circuit pattern layer 130 includes a second pad 130P that overlaps the first through electrode 150 in a vertical direction and is in direct contact with the upper surface of the first through electrode 150, and a trace 130T connected to the second pad 130P.

The first through electrode 150 may include a first metal layer 150-1 and a second metal layer 150-2. The first metal layer 150-1 of the first through electrode 150 may be a plating layer formed on an inner wall of a through hole passing through the first insulating layer 111. For example, the first metal layer 150-1 of the first through electrode 150 may mean a chemical copper plating layer or an electroless plating layer. The first metal layer 150-1 of the first through electrode 150 may correspond to a first metal layer of the second circuit pattern layer 130. For example, the first metal layer 150-1 of the first through electrode 150 may correspond to a first metal layer 130T2 of a trace 120T and a first metal layer 130P2 of a second pad 130P, which will be described below. That is, the first metal layer 150-1 of the first through electrode 150, the first metal layer 130T2 of the trace 120T, and the first metal layer 130P2 of the second pad 130P may be one same metal layer divided according to position.

Additionally, the second metal layer 150-2 of the first through electrode 150 may refer to an electrolytic plating layer formed by electrolytic plating using the first metal layer 150-1 as a seed layer. The second metal layer 150 of the first through electrode 150 may correspond to the second metal layer of the second circuit pattern layer 130. For example, the second metal layer 150-2 of the first through electrode 150 may correspond to a second metal layer 130T3 of a trace 120T and a second metal layer 130P3 of a second pad 130P, which will be described below. The second metal layer 150-2, the second metal layer 130T3 of the trace 120T, and the second metal layer 130P3 of the second pad 130P may be one same metal layer divided according to position.

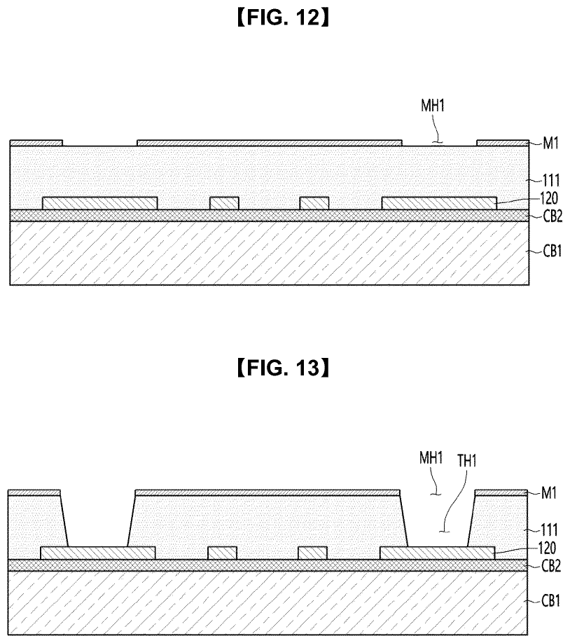

Meanwhile, as described above, the first pad 120P and the trace (not shown) of the first circuit pattern layer 120 may have a structure that includes only the second metal layer corresponding to the electrolytic plating layer. However, the embodiment is not limited thereto, and the first circuit pattern layer 120 may have a same layer structure (e.g., the structure of FIG. 7) as the layer structure of the second circuit pattern layer 130 described below.

Meanwhile, the trace 130T of the second circuit pattern layer 130 may include a copper foil layer 130T1, a first metal layer 130T2, and a second metal layer 130T3.

The copper foil layer 130T1 may be a copper foil layer attached to a surface of the first insulating layer 111 during a process of stacking the first insulating layer 111. For example, the first insulating layer 111 and the copper foil layer 130T1 may constitute RCC (Resin Coated Copper). The first metal layer 130T2 of the trace 120T may correspond to the first metal layer of the first through electrode 150. And, the second metal layer 130T3 of the trace 120T may correspond to the second metal layer 150-2 of the first through electrode 150.

The second pad 130P of the second circuit pattern layer 130 may include a copper foil layer 130P1, a first metal layer 130P2, and a second metal layer 130P3. The copper foil layer 130P1 of the second pad 130P may be a copper foil layer attached to the surface of the first insulating layer 111 during a process of stacking the first insulating layer 111. For example, the first insulating layer 111 and the copper foil layer 130P1 may constitute RCC. The copper foil layer 130P1 of the second pad 130P may correspond to the copper foil layer 130T1 of the trace 130T. The first metal layer 130P2 of the second pad 130P may correspond to the first metal layer 150-1 of the first through electrode 150 and the first metal layer 130T2 of the trace 130T. Here, the first metal layer 130P2 of the second pad 130P may also be referred to as a ‘third metal layer’ extending from the first metal layer 150-1 of the first through electrode 150.

And, the second metal layer 130P3 of the second pad 130P may correspond to the second metal layer 150-2 of the first through electrode 150 and the second metal layer 130T3 of the trace 130T. Here, the second metal layer 130P3 of the second pad 130P may also be referred to as a ‘fourth metal layer’ extending from the second metal layer 150-2 of the first through electrode 150.

Meanwhile, in an embodiment, the first metal layer 130P2 of the second pad 130P may not have a step. For example, the first metal layer 130P2 of the second pad 130P may not directly contact the upper surface of the first insulating layer 111. However, when considering process errors, etc., the first metal layer 130P2 may have a portion in direct contact with the upper surface of the first insulating layer 111. For example, the embodiment may include a step portion where the upper surfaces of the first metal layer 130P2 and the first insulating layer 111 are in direct contact. However, in an embodiment, a horizontal length of the step portion may be formed to be less than or equal to a thickness of the trace 130T. Accordingly, in the embodiment, a length of the step portion can be minimized compared to the comparative example, and accordingly, a size of the through electrode can be minimized.

That is, the first metal layer of the comparative example in FIG. 1D included a step portion (B). For example, the copper foil layer in the comparative example has a structure that exposes part of the upper surface of the insulating layer, and accordingly, the first metal layer of the comparative example includes a portion that is in direct contact with the upper surface of the insulating layer.

Unlike this, the copper foil layer 130P1 of the second pad 130P in the embodiment does not expose the upper surface of the first insulating layer 111. For example, in the embodiment, the upper surface of the first insulating layer 111 may entirely overlap the copper foil layer 130P1 along a vertical direction. Accordingly, in the embodiment, the first metal layer 130P2 of the second pad 130P does not directly contact the upper surface of the first insulating layer 111.

For example, the first metal layer 130P2 of the second pad 130P in the embodiment does not have a step, unlike the comparative example.

Accordingly, in the embodiment, signal loss occurring in the second pad can be minimized compared to the structure of the first metal layer including the step in the comparative example, and communication performance can be improved accordingly.

Meanwhile, in the embodiment, the first metal layer of the first through electrode 150 and the first metal layer 130P2 of the second pad 130P are chemical copper plating layers or electroless plating layers formed integrally.

At this time, a roughness of a surface of the first metal layer of the first through electrode 150 in contact with the through hole of the first insulating layer 111 may be different from a roughness of a surface of the first metal layer 130P2 of the second pad 130P in contact with a side surface of the copper foil layer 130P1.

For example, in the comparative example, the copper foil layer and the insulating layer are simultaneously removed by a laser during the formation of a through hole. As a result, a surface roughness of a side surface of the copper foil layer processed by the laser and a roughness of an inner wall of the through hole of the insulating layer have a substantially similar level. Differently, in a process of forming the through hole in the embodiment, the copper foil layer 130P1 of the second pad 130P is removed by etching, and the first insulating layer 111 is removed by laser processing. Accordingly, the side surface of the copper foil layer 130P1 in the embodiment has a surface roughness caused by the etching process, and the inner wall of the through hole of the first insulating layer 111 has surface roughness caused by a laser process. Accordingly, in the embodiment, the roughness of the surface of the first metal layer of the first through electrode 150 in contact with the inner wall of the through hole of the first insulating layer 111 may be different from the roughness of the surface of the first metal layer 130P2 in contact with the side surface of the copper foil layer 130P1 of the second pad 130P.

Preferably, the roughness of the surface of the first metal layer of the first through electrode 150 in contact with the inner wall of the through hole of the first insulating layer 111 may be greater than the roughness of the surface of the first metal layer 130P2 in contact with the side surface of the copper foil layer 130P1 of the second pad 130P. Through this, the roughness of the surface of the first metal layer 130P2 in contact with the side surface of the copper foil layer 130P1 of the second pad 130P can be reduced, thereby reducing signal loss due to skin effect.

Correspondingly, in an embodiment, an inclination angle of the side surface of the copper foil layer 130P1 of the first pad 120P may be different from an inclination angle of the inner wall of the through hole of the first insulating layer 111.

For example, a first inclination angle of the side surface of the copper foil layer 130P1 may be close to 90 degrees with respect to the upper surface of the first pad 120P. For example, the first inclination angle may range from 85 degrees to 95 degrees. For example, the first inclination angle may range from 87 degrees to 93 degrees. For example, the first inclination angle may range from 88 degrees to 92 degrees.

Alternatively, a second inclination angle of the inner wall of the through hole or the side surface of the first through electrode 150 may be different from the first inclination angle. For example, the second inclination angle may be greater than the first inclination angle. Preferably, the second inclination angle with respect to the upper surface of the first pad 120P may be greater than the first inclination angle. For example, the second inclination angle may range from 96 degrees to 120 degrees. For example, the second inclination angle may range from 97 degrees to 110 degrees. For example, the second inclination angle may range from 98 degrees to 105 degrees. At this time, the second inclination angle may mean an average value of the inclination angle of the inner wall of the through hole or an average value of the inclination angle of the side surface of the first through electrode 150.

Meanwhile, Meanwhile, an angle between the upper surface of the first insulating layer 111 and an upper end of the inner wall of the through hole or an upper end of the side surface of the first through electrode may have an obtuse angle (θ3), and an angle between the lower surface of the first insulating layer 111 and a lower end of the inner wall of the through hole or a lower end of the first through electrode 150 may be an acute angle θ4.

Meanwhile, the first through electrode 150, the first circuit pattern layer 120, and the second circuit pattern layer 130 formed on the first insulating layer 111 have been described above, and accordingly, the second through electrode 160 and the third circuit pattern layer 140 may have a corresponding structure.

As described above, the first circuit pattern layer 120 of the circuit board has a one-layer structure, and the second circuit pattern layer 130 has a three-layer structure.

Alternatively, when the circuit pattern layer of the circuit board is manufactured using the SAP method, the second circuit pattern layer 130 may have a two-layer structure. Hereinafter, the circuit pattern layer and the layer structure of the through electrode of the circuit board manufactured by the SAP method will be described with reference to FIG. 4.

Referring to FIG. 4, the circuit board includes a first through electrode 150 passing through the first insulating layer 111. The circuit board includes a first circuit pattern layer 120 disposed on a lower surface of the first insulating layer 111 and a second circuit pattern layer 130 disposed on an upper surface of the first insulating layer 111.

The first circuit pattern layer 120 includes a first pad 120P that overlaps the first through electrode 150 in a vertical direction and is in direct contact with the lower surface of the first through electrode 150, and a trace (not shown) connected to the first pad 120P.

In addition, the second circuit pattern layer 130 includes a second pad 130Pa that overlaps the first through electrode 150 in a vertical direction and is in direct contact with the upper surface of the first through electrode 150, and a trace 130Ta connected to the second pad 130Pa.

The first through electrode 150 may include a first metal layer 150-1 and a second metal layer 150-2. The first metal layer 150-1 of the first through electrode 150 may be a plating layer formed on an inner wall of the through hole passing through the first insulating layer 111. For example, the first metal layer 150-1 of the first through electrode 150 may mean a chemical copper plating layer or an electroless plating layer. The first metal layer 150-1 of the first through electrode 150 may correspond to a first metal layer 130T2a and 130P2a of the second circuit pattern layer 130.

Additionally, the second metal layer 150-2 of the first through electrode 150 may refer to an electrolytic plating layer formed by electrolytic plating using the first metal layer 150-1 as a seed layer. The second metal layer 150-2 of the first through electrode 150 may correspond to a second metal layer 130T3a and 130P3a of the second circuit pattern layer 130.

Meanwhile, the trace 130Ta of the second circuit pattern layer 130 may include a first metal layer 130T2a and a second metal layer 130T3a.

That is, when the circuit pattern layer is manufactured using the SAP method, the copper foil layer 130T1 may not be included, compared to the circuit pattern layer manufactured using the MSAP method.

The second pad 130Pa of the second circuit pattern layer 130 may include a first metal layer 130P2a and a second metal layer 130P3a.

At this time, the first metal layer 150-1 of the first through electrode 150, the first metal layer 130T2a of the trace 120T, and the first metal layer 130P2a of the second pad 130P may be one same metal layer divided according to position.

In addition, the second metal layer 150-2 of the first through electrode 150, the second metal layer 130T3a of the trace 120T, and the second metal layer 130P3a of the second pad 130P may be one same metal layer divided according to position.

Here, the first metal layer 130P2 of the second pad 130P may also be referred to as a ‘third metal layer’ extending from the first metal layer 150-1 of the first through electrode 150.

In addition, the second metal layer 130P3 of the second pad 130P may correspond to the second metal layer 150-2 of the first through electrode 150 and the second metal layer 130T3 of the trace 130T. Here, the second metal layer 130P3 of the second pad 130P2 may also be referred to as a ‘fourth metal layer’ extending from the second metal layer 150-2 of the first through electrode 150.

To summarize the structures of FIGS. 3 and 4, when the circuit pattern layer is manufactured by the MSAP method, the pad and trace of the second circuit pattern layer 130 have a layer structure including a copper foil layer (e.g., a three-layer structure). Additionally, when the circuit pattern layer is manufactured using the SAP method, the pad and trace of the second circuit pattern layer 130 may have a layer structure (e.g., a two-layer structure) that does not include the copper foil layer.

Meanwhile, hereinafter, a structure of the through electrode according to the embodiment will be described in more detail.

The through electrode in the embodiment may be a small through electrode or a fine through electrode. Here, the small or fine through electrode may mean that there is little difference between a first width of a widest portion and the second width of a narrowest portion in an entire region in a thickness direction of the through electrode.

At this time, in a general circuit board, an insulating layer is formed using a photosensitive material to form a small through electrode or fine through electrode. For example, it is known that the insulating layer on a general circuit board forms a through electrode by applying PID (Photo Imageable Dielectric), a photosensitive material, to implement a small through electrode.

However, PID, which is generally a photosensitive material, has a dielectric constant (Dk) exceeding 3.0, and accordingly, it is difficult to apply it to boards that use frequencies higher than those for 5G. For example, in a 5G board, a dielectric constant of the board must be low. However, the dielectric constant of general PID exceeds 3.0. Accordingly, when applying the PID to a 5G board, there is a problem that signal transmission loss increases when transmitting a large signal.

In addition, when a circuit board is implemented using a PID, a sputter, which is a deposition equipment, must be used in the plating process for circuit formation on the circuit board including the PID, which has the problem of increasing process costs. Furthermore, in the circuit board including the PID, there is a problem in that the adhesion between the insulating layer composed of the PID and the circuit pattern is low, and as a result, the circuit pattern is separated from the insulating layer. For example, the circuit board including a PID requires a high process temperature (e.g., 250 degrees or more) during the circuit pattern formation process or soldering process. Due to such a high processing temperature, the adhesion between the PID and the circuit pattern is reduced, causing the circuit pattern to be separated from the insulating layer.

Accordingly, in the embodiment, the insulating layer 110 is configured using RCC. The RCC has a structure in which a copper foil layer is attached to an insulating layer, and accordingly, an adhesion between the insulating layer and the copper foil layer is higher than that of a circuit board using PID. Furthermore, RCC has a low dielectric constant (Dk) in a range of 2.0 to 3.0, and therefore can be applied to products that transmit signals in the high frequency band for 5G.

That is, the insulating layer 110 in the embodiment may have a dielectric constant (Dk) between 2.0 and 3.0. If the dielectric constant of the insulating layer 110 is less than 2.0, there is a problem that the processability of the material is reduced. For example, if the dielectric constant of the insulating layer 110 is less than 2.0, the strength is weak, bending characteristics may deteriorate during the formation of through electrodes or circuit patterns, and process characteristics are deteriorated. Additionally, if the dielectric constant (Dk) of the insulating layer 110 exceeds 3.0, there is a problem of increased signal loss.

Accordingly, the insulating layer 110 in the embodiment has a dielectric constant (Dk) between 2.0 and 3.0. For example, the insulating layer 110 in the embodiment may be formed of RCC or prepreg having a dielectric constant (Dk) between 2.0 and 3.0. Accordingly, the embodiment may provide a circuit board having a low dielectric constant, and accordingly, it can be applied to 5G products and solves the reliability problem of the PID.

At this time, the RCC or prepreg as described above has a structure including a copper foil layer. Therefore, as in the comparative example, there may be difficulties in a process of forming a through hole by processing the copper foil layer and insulating layer with a laser.

On the other hand, in the embodiment, when forming a through hole in an insulating layer on which a copper foil layer is laminated, the copper foil layer is first removed. For example, in the embodiment, a portion of the copper foil layer corresponding to a location where the through hole is formed is first removed by etching. And, in the embodiment, a laser processing process is performed on a surface of the insulating layer exposed through removal of the copper foil layer to form a through hole of a desired size. Accordingly, in the embodiment, only the insulating layer needs to be processed in the through hole forming process, and thus the intensity of the laser can be lowered compared to the comparative example. Through this, in the embodiment, the difference value between the maximum and minimum widths of the through hole can be reduced, and accordingly, it is possible to form a small or fine through electrode.

For example, the through electrode 150 in the embodiment may have a first width W1 at an upper surface. For example, in the embodiment, the upper surface of the through electrode 150 may have a first width W1. The first width W1 may mean a maximum width at the upper surface of the through electrode 150. For example, the width of the upper surface of the through electrode 150 may be different in a width direction, a longitudinal direction, and a plurality of diagonal directions therebetween. And, the first width W1 may mean a greatest width among the widths in each direction (for example, a width in a direction with the greatest width).

Alternatively, the first width W1 may mean an average value of the width of the upper surface of the through electrode 150 in each direction.

Meanwhile, the through electrode 150 according to an embodiment may have a second width W2 at a first region. The first region of the through electrode 150 may mean a region below the upper surface of the through electrode 150. For example, the first region of the through electrode 150 may mean a region including a lower surface of the through electrode 150 below the upper surface.

The through electrode 150 according to an embodiment may have a second width W2, which is the minimum width at the first region. For example, the second width W2 may mean a width of a lower surface of the through electrode 150, but is not limited thereto.

At this time, when a through hole is formed through a laser process, an ideal shape of the through hole has a trapezoidal shape with the width gradually narrowing from an upper portion to a lower portion. Accordingly, the through electrode filling the inside of the through hole as described above has the maximum width at the upper surface and the minimum width at the lower surface. However, due to the material characteristics of the insulating layer and processing characteristics in the laser process, the through hole and through electrode do not have a trapezoidal shape. For example, as shown in FIG. 6, a vertical cross section of the through hole has a shape in which the width changes irregularly rather than a trapezoidal shape in which the width gradually changes in a thickness direction.

In addition, in the embodiment, the second width W2 may mean a width of a region having a smallest width among all regions in a thickness direction of the through electrode 150. In other words, the first region may mean a region with a minimum width among all regions in the thickness direction of the through electrode 150.

Meanwhile, the minimum width of the through electrode in the comparative example was less than 60% of the maximum width of the through electrode.

In contrast, the second width W2 of the through electrode 150 in the embodiment may range from 70% to 99% of the first width W1. For example, in an embodiment, the second width W2 of the through electrode 150 may range from 75% to 90% of the first width W1. For example, in an embodiment, the second width W2 of the through electrode 150 may range from 80% to 85% of the first width W1.

If the second width W2 of the through electrode 150 is smaller than 70% of the first width W1, it is difficult to miniaturize the through electrode. Additionally, if the second width W2 of the through electrode 150 is less than 70% of the first width W1, there is a problem in that the loss of the signal transmitted through the through electrode 150 increases. Additionally, if the second width W2 of the through electrode 150 is greater than 99% of the first width W1, there is a problem in that laser processability is deteriorated.

For example, the first width W1 of the through electrode 150 may satisfy a range of 20 μm to 45 μm. For example, the first width W1 of the through electrode 150 may satisfy a range of 22 μm to 42 μm. For example, the first width W1 of the through electrode 150 may satisfy a range of 25 μm to 40 μm.

For example, the second width W2 of the through electrode 150 may satisfy a range of 14 μm to 44.5 μm. For example, the second width W2 of the through electrode 150 may satisfy a range of 15.5 μm to 41.5 μm. For example, the second width W2 of the through electrode 150 may satisfy a range of 17.5 μm to 39.5 μm.

Meanwhile, in the embodiment, one-half (½) value of the difference (ΔW1) between the first width W1 and the second width W2 of the through electrode 150 may range from 0.1% to 15% of the first width W1. For example, in the embodiment, one-half (½) value of the difference (ΔW1) between the first width W1 and the second width W2 of the through electrode 150 may range from 1% to 15% of the first width W1. For example, in the embodiment, one-half (½) value of the difference (ΔW1) between the first width W1 and the second width W2 of the through electrode 150 may range from 2% to 10% of the first width W1.

In the embodiment, if one-half (½) of the difference (ΔW1) between the first width W1 and the second width W2 of the through electrode 150 is greater than 15% of the first width W1, there is a problem in that it is difficult to miniaturize the size of the through electrode, and the loss in the signal transmitted through the through electrode 150 increases. In addition, if one-half (½) value of the difference (ΔW1) between the first width W1 and the second width W2 of the through electrode 150 in the embodiment is less than 0.1%, there is a problem that laser processability is deteriorated.

As described above, in the embodiment, the difference value between the first width W1 of the upper surface of the through electrode 150 and the second width W2 of the smallest width part of the entire region of the through electrode 150 is minimized. Accordingly, it is possible to miniaturize the through electrode 150. Furthermore, in the embodiment, the difference between the first and second widths of the through electrode is minimized, thereby minimizing signal transmission loss.

Meanwhile, in the embodiment, as the difference between the first width W1 and the second width W2 of the through electrode 150 is minimized as described above, the width W3 of the first pad 120P disposed on the lower surface of the through electrode 150 and the width W4 of the second pad 130P disposed on the upper surface of the through electrode 150 can be reduced.

For example, in the comparative example, a step region existed on the upper surface of the through electrode, and the width of the pad disposed on the upper surface of the through electrode had to be increased to correspond to the step region. For example, in the comparative example, the width of the pad was determined to correspond to the size in the step region.

In contrast, in the embodiment, the step region of the through electrode can be removed, and further, the difference value between the first width W1 and the second width W2 of the through electrode can be minimized. Accordingly, in the embodiment, the width W3 of the first pad 120P disposed on the lower surface of the through electrode 150 and the width W4 of the second pad 130P disposed on the upper surface of the through electrode 150 can be reduced.

For example, a width W3 of the first pad 120P may be determined based on a width of a lower surface of the through electrode 150. For example, the width W3 of the first pad 120P may be determined based on the second width W2 of the through electrode 150.

For example, the width W3 of the first pad 120P may satisfy a range of 102% to 140% of the second width W2 of the through electrode 150. For example, the width W3 of the first pad 120P may satisfy a range of 105% to 135% of the second width W2 of the through electrode 150. For example, the width W3 of the first pad 120P may satisfy a range of 108% to 130% of the second width W2 of the through electrode 150. That is, the width W3 of the first pad 120P3 may be determined based on the second width W2 of the through electrode 150. Also, in the embodiment, the second width W2 of the through electrode 150 can be reduced compared to the comparative example, and the width W3 of the first pad 120P3 can be correspondingly reduced. Meanwhile, the width W3 of the first pad 120P may mean a width in a direction having a minimum width among the widths in each direction. Alternatively, the width W3 of the first pad 120P may mean an average value of the width of the first pad 120P in each direction.

Meanwhile, in the embodiment, the first width W1 of the through electrode 150 may be further reduced than the second width W2 of the through electrode 150, compared to the comparative example.

In addition, the first width W1 of the through electrode 150 reduces compared to the comparative example, so that the width W4 of the second pad 130P disposed on the upper surface of the through electrode 150 can be further reduced. That is, the width W4 of the second pad 130P may be determined based on the first width of the through electrode 150.

The width W4 of the second pad 130P may mean a width in a direction having the minimum width among the widths of the second pad 130P in each direction. Alternatively, the width W4 of the second pad 130P may mean an average value of the widths of the second pad 130P in each direction.

For example, a width of an upper surface of the second pad 130P may be different in a width direction, a longitudinal direction, and a plurality of diagonal directions therebetween. And, the width W4 of the second pad 130P may mean a minimum width (for example, a width in a direction having a smallest width) among the widths in each direction. Alternatively, the width W4 of the second pad 130P may mean an average value of the widths of the second pad 130P in each direction.

In the embodiment, one-half (½) of a difference value between the width W4 of the second pad 130P and the second width W2 of the through electrode 150 may be greater than 0.01 μm and less than or equal to 4.0 μm. For example, one-half (½) of the difference value between the width W4 of the second pad 130P and the second width W2 of the through electrode 150 may be greater than 0.01 μm and less than or equal to 3.0 μm. For example, one-half (½) of the difference value between the width W4 of the second pad 130P and the second width W2 of the through electrode 150 may be greater than 0.01 μm and less than or equal to 2.0 μm. For example, one-half (½) of the difference value between the width W4 of the second pad 130P and the second width W2 of the through electrode 150 may be greater 0.01 μm and less than or equal to 1.0μm.

That is, in the comparative example, one-half (½) of the difference value between the width of the second pad and the minimum width of the through electrode due to the difference between the maximum width (e.g., first width) and minimum width (e.g., second width) of the through electrode exceeds 4.5 μm as described above.

On the other hand, the embodiment may allow one-half (½) of the difference value between the width W4 of the second pad 130P and the second width W2 of the through electrode to be managed to 4.0 μm or less, further 3.0 μm or less, furthermore, 2.0 μm or less, and furthermore, 1.0 μm or less, and thus the second pad 130P can be miniaturized, thereby improving circuit integration.

In addition, in the embodiment, one-half (½) of the difference value between the width W4 of the second pad 130P and the first width W1 of the through electrode 150 may range between 0.75 μm to 2.97 μm. For example, in the embodiment, one-half (½) of the difference value between the width W4 of the second pad 130P and the first width W1 of the through electrode 150 may range between 1.0 μm and 2.2 μm. For example, in the embodiment, one-half (½) of the difference value between the width W4 of the second pad 130P and the first width W1 of the through electrode 150 may range between 1.2 μm and 2.0 μm. Through this, in the embodiment, a size of the second pad 130P can be reduced by miniaturizing the through electrode 150, and further, circuit integration can be improved.

The embodiment manufactures a circuit board using RCC or prepreg rather than a photosensitive material. That is, PID, which is generally a photosensitive material, has a dielectric constant (Dk) exceeding 3.0, and accordingly, it is difficult to apply it to boards that use frequencies higher than those for 5G. For example, in a 5G board, a dielectric constant of the board must be low. However, the dielectric constant of general PID exceeds 3.0. Accordingly, when applying the PID to a 5G board, there is a problem that signal transmission loss increases when transmitting a large signal. In addition, when a circuit board is implemented using a PID, a sputter, which is a deposition equipment, must be used in the plating process for circuit formation on the circuit board including the PID, which has the problem of increasing process costs. Furthermore, in the circuit board including the PID, there is a problem in that the adhesion between the insulating layer composed of the PID and the circuit pattern is low, and as a result, the circuit pattern is separated from the insulating layer. For example, the circuit board including a PID requires a high process temperature (e.g., 250 degrees or more) during the circuit pattern formation process or soldering process. Due to such a high processing temperature, the adhesion between the PID and the circuit pattern is reduced, causing the circuit pattern to be separated from the insulating layer.

Accordingly, the insulating layer in the embodiment may be formed of RCC or prepreg having a dielectric constant (Dk) between 2.0 and 3.0. Accordingly, the embodiment provides a circuit board with a low dielectric constant, enabling application to 5G products and solving the reliability problem of the PID.

Meanwhile, the insulating layer containing RCC or prepreg has limitations in forming small through electrodes. At this time, the embodiment allows the copper foil layer to be removed first when forming a through hole in an insulating layer in which a copper foil layer is laminated on its surface. For example, the embodiment allows some regions of the copper foil layer corresponding to locations where through holes were formed to be preferentially removed by etching. And, in the embodiment, a laser processing process is performed on the surface of the insulating layer exposed through removal of the copper foil layer to form a through hole of a desired size. Accordingly, in the embodiment, only the insulating layer needs to be processed in the through hole forming process, and thus an intensity of the laser can be lowered compared to a comparative example. Through this, the embodiment can reduce the difference between the maximum and minimum width of the through hole, thereby enabling the formation of a small through electrode.

Meanwhile, when performing a process of forming a through hole passing through the insulating layer, the comparative example proceeds a process of removing the insulating layer and the copper foil layer on the insulating layer. Accordingly, conditions of the laser process in the comparative example enable processing of the copper foil layer. Accordingly, the comparative example has a laser intensity greater than that of the embodiment. Through this, in the comparative example, a thickness of the first circuit pattern layer, which functions as a laser stopper in the laser processing process, increased. That is, when a thickness of the first circuit pattern layer becomes thin, a reliability problem of penetration of the first circuit pattern layer occurs due to the laser in the laser processing process. Accordingly, the comparative example had a thickness of the first circuit pattern layer of at least 15 μm to solve the problem of penetration by the laser.

Unlike this, in the embodiment, in the process of forming the through hole, the copper foil layer is preferentially removed by etching. Accordingly, the laser intensity for forming the through hole in the embodiment may be lower than that in the comparative example.

Accordingly, in the embodiment, a thickness of the first circuit pattern layer 120, which functions as a stopper in the process of forming the through hole of the first through electrode 150, can be reduced. And, in the embodiment, even if the thickness of the first circuit pattern layer 120 is reduced, the problem of the first circuit pattern layer 120 being penetrated during the process of forming the through hole can be solved by performing laser processing under relatively low intensity conditions.

For example, a thickness T1 of the first circuit pattern layer 120 in the embodiment may range from 1.0 μm to 12 μm. For example, the thickness T1 of the first circuit pattern layer 120 in the embodiment may range from 1.5 μm to 11 μm. For example, the thickness T1 of the first circuit pattern layer 120 in the embodiment may range from 2.0 μm to 10 μm. Through this, the embodiment can reduce the thickness T1 of the first circuit pattern layer 120 to reduce the thickness of the first insulating layer 111, thereby slimming the overall thickness of the circuit board.

Meanwhile, a thickness T2 of the second circuit pattern layer 130 in the embodiment may correspond to the thickness T1 of the first circuit pattern layer 120. For example, the thickness T2 of the second circuit pattern layer 130 in the embodiment may range from 1.0 μm to 12 μm. For example, the thickness T2 of the second circuit pattern layer 130 in the embodiment may range from 1.5 μm to 11 μm. For example, the thickness T2 of the second circuit pattern layer 130 in the embodiment may range from 2.0 μm to 10 μm. Through this, the embodiment can reduce the thickness T2 of the second circuit pattern layer 130 to reduce the thickness of the second insulating layer 112, thereby slimming the overall thickness of the circuit board

Meanwhile, the thickness T1 of the first circuit pattern layer 120 may mean a sum of the thicknesses of all layers constituting the first circuit pattern layer 120. For example, when the first circuit pattern layer 120 has a plurality of layer structure, the thickness T1 may mean a sum of thicknesses of the plurality of layers.

In addition, the thickness T2 of the second circuit pattern layer 130 may mean a sum of the thicknesses of each layer of the second circuit pattern layer 130. For example, when the second circuit pattern layer 130 has a three-layer structure, the thickness T2 may mean a sum of thicknesses of the copper foil layer, the first metal layer, and the second metal layer. For example, when the second circuit pattern layer 130 has a two-layer structure, the thickness T2 may mean a sum of thicknesses of the first metal layer and the second metal layer.

Meanwhile, in circuit boards for 5G or higher, signals in the high frequency band are transmitted through the circuit pattern layer. At this time, the signal in the high frequency band has the characteristic of moving along a surface of the circuit pattern layer. Additionally, when a roughness of the circuit pattern layer increases or a surface area of the circuit pattern layer increases, signal transmission loss increases due to a skin effect. At this time, in the embodiment, the thickness of the first circuit pattern layer 120 and the second circuit pattern layer 130 may be reduced compared to the comparative example as described above. Through this, in the embodiment, the surface areas of the first circuit pattern layer 120 and the second circuit pattern layer 130 can be reduced, as a result, signal transmission loss can be minimized.

In addition, in the embodiment, the thickness of the circuit pattern layer can be reduced compared to the comparative example, and accordingly, the thickness of the insulating layer can also be reduced compared to the comparative example.

For example, a general insulating layer has a thickness to stably protect the circuit pattern layer and to stably insulate the circuit pattern layers of different neighboring layers. For example, the thickness of the circuit pattern layer in the comparative example is 15 μm to 30 μm. Accordingly, the thickness of the insulating layer in the comparative example ranges from 15 μm to 60 μm, which is 1 to 2 times the thickness of the circuit pattern layer.

Unlike this, the embodiment allows the thickness of the circuit pattern layer to be reduced compared to the comparative example, and accordingly, the thickness of the insulating layer can be correspondingly reduced.

Here, the thickness of the insulating layer may mean a distance between circuit pattern layers disposed in different neighboring layers.

For example, a thickness of the first insulating layer 111 may refer to a vertical distance between an upper surface of the first circuit pattern layer 120 and a lower surface of the second circuit pattern layer 130. For example, a thickness of the second insulating layer 112 may refer to a vertical distance between an upper surface of the second circuit pattern layer 130 and a lower surface of the third circuit pattern layer 140.

And, in an embodiment, the thickness of the first insulating layer 111 may also be reduced corresponding to a decrease in the thickness of the first circuit pattern layer 120.

Preferably, the thickness of the first insulating layer 111 may range from 1.0 μm to 24 μm. For example, the thickness of the first insulating layer 111 may range from 1.5 μm to 22 μm. For example, the thickness of the first insulating layer 111 in the embodiment may range from 2.0 μm to 20 μm.

In addition, in an embodiment, the thickness of the second insulating layer 112 may be reduced corresponding to a decrease in the thickness of the second circuit pattern layer 130.

Preferably, the thickness of the second insulating layer 112 may range from 1.0 μm to 24 μm. For example, the thickness of the second insulating layer 112 may range from 1.5 μm to 22 μm. For example, in an embodiment, the thickness of the second insulating layer 112 may range from 2.0 μm to 20 μm.

The embodiment allows for miniaturization of the through electrode by changing the method of forming the through electrode. Accordingly, the embodiment can reduce the thickness of the circuit pattern layer (e.g., pad) connected to the through electrode, and further reduce the thickness of the insulating layer in response to the decrease in the thickness of the circuit pattern layer. Through this, the embodiment enables slimming of the circuit board.

FIG. 7 is a view showing a circuit board according to a second embodiment.

The circuit board of FIG. 7 is different from the circuit board of FIG. 2 in an arrangement structure of the circuit pattern layer. For example, the circuit board in FIG. 2 has an ETS structure.

Alternatively, the circuit board of FIG. 7 may have a structure in which all of the outermost circuit pattern layers protrude above a surface of the insulating layer.

For example, the circuit board includes an insulating layer 210 including a first insulating layer 211 and a second insulating layer 212.

In addition, the circuit board includes a first circuit pattern layer 220 protruding below a lower surface of the first insulating layer 211.

In addition, the circuit board includes a second circuit pattern layer 230 disposed between the first insulating layer 211 and the second insulating layer 212.

In addition, the circuit board includes a third circuit pattern layer 240 protruding on an upper surface of the second insulating layer 212.

Meanwhile, in a case of a structure of FIG. 7, the first circuit pattern layer 220 may have a three-layer structure including a copper foil layer, a first metal layer, and a second metal layer as shown in FIG. 3 or a two-layer structure including a first metal layer and a second metal layer, unlike the first circuit pattern layer 120 of FIG. 2.

In addition, the circuit board includes a first through electrode 250 passing through the first insulating layer 211 and a second through electrode 260 passing through the second insulating layer 212. In addition, the circuit board includes a first protective layer 270 disposed on a lower surface of the first insulating layer 211 and a second protective layer 280 disposed on an upper surface of the second insulating layer 212.

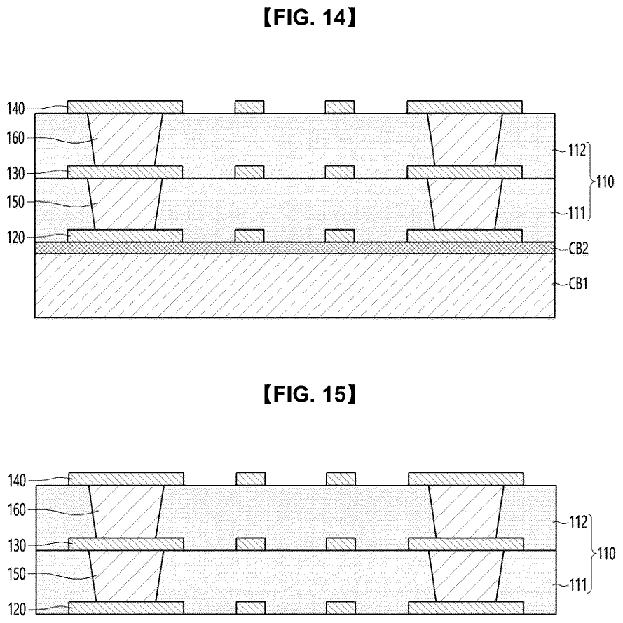

FIG. 8 is a view showing a semiconductor package according to an embodiment.

The semiconductor package of the embodiment may have a structure in which at least one chip is mounted on the circuit board of FIG. 2 or FIG. 7.

For example, the semiconductor package may include a connection part 310 disposed on a pad (not shown) of the third circuit pattern layer 140 disposed on a first outermost side of the circuit board.

The connection part 310 may have a spherical shape. For example, a cross section of the connection part 310 may include a circular shape or a semicircular shape. For example, a cross section of the connection part 310 may include a partially or entirely rounded shape. A cross-sectional shape of the connection part 310 may be flat on one side and curved on the other side. The connection part 310 may be a solder ball, but is not limited thereto.

Alternatively, the connection part 310 may have a hexahedral shape. For example, a cross section of the connection part 310 may have a rectangular shape. A cross section of the connection part 310 may include a rectangle or square.

The semiconductor package of the embodiment may include a chip 320 disposed on the connection part 310. The chip 320 may be a processor chip. For example, the chip 320 may be an application processor (AP) chip of any one of a central processor (e.g., CPU), graphics processor (e.g., GPU), digital signal processor, cryptographic processor, microprocessor, and microcontroller.

At this time, a terminal 325 may be included on a lower surface of the chip 320, and the terminal 325 may be electrically connected to the first circuit pattern layer 120 of the circuit board through the connection part 310.

Meanwhile, the semiconductor package of the embodiment may allow a plurality of chips to be arranged at a certain distance from each other on one circuit board. For example, the chip 320 may include a first chip and a second chip that are spaced apart from each other.

Also, the first chip and the second chip may be different types of application processor (AP) chips.

Meanwhile, the first chip and the second chip may be spaced apart from each other at a certain distance on the circuit board. For example, a distance between the first chip and the second chip may be 150 μm or less. For example, a distance between the first chip and the second chip may be 120 μm or less. For example, a distance between the first chip and the second chip may be 100 μm or less.

Preferably, for example, a distance between the first chip and the second chip may range from 60 μm to 150 μm. For example, a distance between the first chip and the second chip may range from 70 μm to 120 μm. For example, a distance between the first chip and the second chip may range from 80 μm to 110 μm. For example, if the distance between the first chip and the second chip is less than 60μm, interference between the first chip and the second chip may occur, which may cause problems with the operational reliability of the first chip or the second chip. For example, if the distance between the first chip and the second chip is greater than 150μm, signal transmission loss may increase as the distance between the first chip and the second chip increases.

The semiconductor package may include a molding layer 330. The molding layer 330 may be disposed to cover the chip 320. For example, the molding layer 330 may be EMC (Epoxy Mold Compound) formed to protect the mounted chip 320, but is not limited thereto.

At this time, the molding layer 330 may have a low dielectric constant to increase heat dissipation characteristics. For example, the dielectric constant (Dk) of the molding layer 330 may be 0.2 to 10. For example, the dielectric constant (Dk) of the molding layer 330 may be 0.5 to 8. For example, the dielectric constant (Dk) of the molding layer 330 may be 0.8 to 5. Accordingly, in the embodiment, the molding layer 330 has a low dielectric constant to improve heat dissipation characteristics for heat generated from the chip 320.

Meanwhile, the semiconductor package may include a solder ball 340 disposed on a lowermost side of the circuit board. The solder ball 340 may be used for bonding to an external substrate (e.g., a main board of an external device).

Hereinafter, a method of manufacturing a circuit board according to an embodiment will be described.

At this time, in the method for manufacturing the circuit board of the embodiment, it is substantially the same as the prior art except for the process of forming a through electrode, and accordingly, a description will be based on a process of forming a through electrode in at least one layer among a plurality of layers.

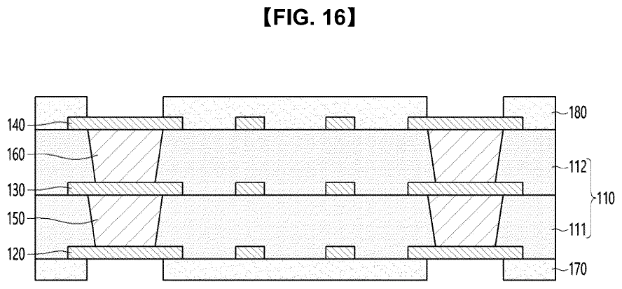

FIGS. 9 to 16 are views showing the manufacturing method of the circuit board shown in FIG. 2 in order of processes.

Hereinafter, the method for manufacturing the circuit board shown in FIG. 2 will be described in detail with reference to the drawings.

Referring to FIG. 9, the embodiment prepares a carrier board. For example, the embodiment proceeds with a process of preparing a carrier board including a carrier insulating layer CB1 and a carrier metal layer CB2, which are basic materials for the manufacture of circuit boards with an ETS structure.

Next, referring to FIG. 10, the embodiment proceeds with a process of forming a mask DF1 on the carrier metal layer CB2. The mask DF1 may be a dry film, but is not limited thereto. The mask DF1 includes at least one opening (not shown). For example, the mask DF1 includes an opening that vertically overlaps a region of the upper surface of the carrier metal layer CB2 where the first circuit pattern layer 120 will be formed. Next, the embodiment performs electrolytic plating using the carrier metal layer CB2 as a seed layer to form the first circuit pattern layer 120 that fills the opening of the mask DF1.

Next, referring to FIG. 11, the embodiment proceeds with a process of forming a first insulating layer 111 on the carrier metal layer CB2 and the first circuit pattern layer 120. The first insulating layer 111 may be RCC. Accordingly, a copper foil layer M1 may be formed on an upper surface of the first insulating layer 111.

Next, the embodiment may proceed with a process of forming a through hole passing through the first insulating layer 111.

At this time, in the comparative example, the first insulating layer 111 and the copper foil layer M1 are simultaneously opened through a laser process to form a through hole.

Unlike this, in the embodiment, the through hole is formed in a plurality of steps.

To this end, referring to FIG. 12, the embodiment can proceed with an etching process to remove a region where a through hole will be formed in the copper foil layer M1. Specifically, the embodiment can proceed with a process of forming a hole MH1 in the copper foil layer M1.

A size of the hole MH1 formed in the copper foil layer M1 may correspond to a size of a through hole to be formed in the first insulating layer 111.

Next, referring to FIG. 13, the embodiment can proceed with a process of forming a through hole by irradiating a laser to a surface of the first insulating layer 111 exposed the hole MH1 in the copper foil layer M1.

For example, the embodiment can proceed with a process of forming a first through hole VH1 penetrating the first insulating layer 111 by irradiating a laser to the upper surface of the first insulating layer 111 exposed through the hole MH1 formed in the copper foil layer M1.

Next, as shown in FIG. 14, the embodiment may proceed with a process of forming a second circuit pattern layer 130 on the first through electrode 150 that fills the first through hole TH1 and the first insulating layer 111. In addition, the embodiment may repeatedly proceed with the processes of FIGS. 11 to 13. That is, the embodiment may proceed with a process of laminating a second insulating layer 112 on the first insulating layer 111, a process of forming a second through electrode 160 penetrating the second insulating layer 112, and a process of forming the third circuit pattern layer 140 on the second insulating layer 112.

Next, as shown in FIG. 15, the embodiment may proceed with a process of separating the carrier insulating layer CB1 from the carrier metal layer CB2. Next, the embodiment may proceed with a process of removing the carrier metal layer (CB2) by etching.

Next, as shown in FIG. 16, the embodiment may proceed with a process of forming a first protective layer 170 on the lower surface of the first insulating layer 111 and a process of forming a second protective layer 180 on the upper surface of the second insulating layer 112.

The characteristics, structures, effects, and the like described in the above-described embodiments are included in at least one embodiment, but are not limited to only one embodiment. Furthermore, the characteristic, structure, and effect illustrated in each embodiment may be combined or modified for other embodiments by a person skilled in the art. Therefore, it should be construed that contents related to such combination and modification are included in the scope of the embodiment.

Embodiments are mostly described above, but the embodiments are merely examples and do not limit the embodiments, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the embodiment defined in the following claims.

1.-10. (canceled)

11. A circuit board comprising:
an insulating layer;
an upper pad disposed on the insulating layer; and
a through electrode formed in a through hole passing through the insulating layer and connected to the upper pad,
wherein the upper pad includes a pad layer disposed on an upper surface of the insulating layer and having an opening overlapping the through hole in a vertical direction, and
wherein an inclination angle of an inner wall of the pad layer forming the opening is different from an inclination angle of an inner wall of the insulating layer forming the through hole.

12. The circuit board of claim 11, wherein the upper pad is in contact with an upper surface of the through electrode and has a thickness in a range of 1.0 μm to 12 μm.

13. The circuit board of claim 12, wherein the through electrode has a first width at an upper surface and a second width less than the first width at a first region below the upper surface,
wherein the first region is a region with a smallest width in an entire region in a thickness direction of the through electrode, and
wherein the second width satisfies a range of 70% to 99% of the first width.

14. The circuit board of claim 13, wherein the first width is one of a maximum width and an average width of the upper surface of the through electrode.

15. The circuit board of claim 13, wherein one half of a difference value between the first width and the second width of the through electrode satisfies a range of 0.1% to 20% of the first width.

16. The circuit board of claim 13, wherein the upper pad has a third width, and
wherein one half of a difference value between the third width of the upper pad and the second width of the through electrode is 4.0 μm or less.

17. The circuit board of claim 13, wherein the upper pad has a third width, and
wherein one half of a difference value between the third width of the upper pad and the first width of the through electrode satisfies a range of 0.75 μm to 2.97 μm.

18. The circuit board of claim 13, wherein the through electrode includes:
a first metal layer formed on the inner wall of the through hole; and
a second metal layer formed on the first metal layer and filling the through hole, and wherein the upper pad includes:
a third metal layer disposed on the pad layer and extending from the first metal layer; and
a fourth metal layer extending from the second metal layer.

19. The circuit board of claim 12, further comprising:
a lower pad disposed on a lower surface of the insulating layer and connected to a lower surface of the through electrode,
wherein the lower pad has a thickness in a range of 1.0 μm to 12 μm.

20. The circuit board of claim 18, wherein the third metal layer of the upper pad does not directly contact the upper surface of the insulating layer.

21. The circuit board of claim 18, wherein the inner wall of the pad layer of the upper pad is in contact with the third metal layer.

22. The circuit board of claim 11, wherein the inclination of the inner wall of the pad layer is closer to 90 degrees than the inclination of the inner wall of the through hole.

23. A semiconductor package comprising:
an insulating layer;
an upper pad disposed on the insulating layer;
a through electrode formed in a through hole passing through the insulating layer and connected to the upper pad; and
a semiconductor device disposed on the insulating layer,
wherein the upper pad includes a pad layer disposed on an upper surface of the insulating layer and having an opening overlapping the through hole in a vertical direction, and
wherein an inclination angle of an inner wall of the pad layer forming the opening is different from an inclination angle of an inner wall of the insulating layer forming the through hole.

24. The semiconductor package of claim 23, wherein the upper pad is in contact with an upper surface of the through electrode and has a thickness in a range of 1.0 μm to 12 μm.

25. The semiconductor package of claim 24, wherein the through electrode has a first width at an upper surface and a second width less than the first width at a first region below the upper surface,
wherein the first region is a region with a smallest width in an entire region in a thickness direction of the through electrode, and
wherein the second width satisfies a range of 70% to 99% of the first width.

26. The semiconductor package of claim 24, wherein one half of a difference value between the first width and the second width of the through electrode satisfies a range of 0.1% to 20% of the first width.

27. The semiconductor package of claim 24, wherein the upper pad has a third width, and
wherein one half of a difference value between the third width of the upper pad and the second width of the through electrode is 4.0 μm or less.

28. The semiconductor package of claim 23, wherein the through electrode includes:
a first metal layer formed on the inner wall of the through hole; and
a second metal layer formed on the first metal layer and filling the through hole, and wherein the upper pad includes:
a third metal layer disposed on the pad layer and extending from the first metal layer; and
a fourth metal layer extending from the second metal layer.

29. The semiconductor package of claim 28, wherein the third metal layer of the upper pad does not directly contact the upper surface of the insulating layer, and
wherein the inner wall of the pad layer of the upper pad is in contact with the third metal layer.

30. The semiconductor package of claim 23, wherein the inclination of the inner wall of the pad layer is closer to 90 degrees than the inclination of the inner wall of the through hole.
